(19) United States
(12) Patent Application Publication
(10) Pub. No.: US 2020/0343306 A1
(43) Pub. Date: Oct. 29, 2020

(54) RRAM-BASED CROSSBAR ARRAY CIRCUITS

(71) Applicant: TETRAMEM INC., Newark, CA (US)

(72) Inventors: Minxian Zhang, Newark, CA (US); Ning Ge, Newark, CA (US)

(73) Assignee: TETRAMEM INC., Newark, CA (US)

(21) Appl. No.: 16/395,867

(22) Filed: Apr. 26, 2019

(51) Int. Cl. H01L 27/24; H01L 45/00

(52) U.S. Cl. CPC H01L 27/2463; H01L 45/146; H01L 45/147; H01L 27/2436; H01L 45/08; H01L 45/1233; H01L 45/1253

(57) ABSTRACT

Technologies relating to improving LRS data retention and reliability in RRAM-based crossbar array circuits are disclosed. An example apparatus includes: a bottom electrode; a filament forming layer formed on the bottom electrode; and a top electrode formed on the filament forming layer. The filament forming layer is configured to form a filament within the filament forming layer responsive a switching voltage being applied to the filament forming layer. The filament forming layer may be made of one of the following materials: HfOxSiy, HfOxNy, HfOxAly, HfOx doped with SiO2, HfOx doped with Al2O3, HfOx doped with N, HfOx doped with Si₃N₄, HfOx doped with AlN, or a combination thereof. The bottom electrode or the top electrode may be made of one of the following materials: Pt, Ti, TiN, Pd, Ir, W, Ta, Hf, Nb, V, Ru, TaN, NbN, a combination therefore, or an alloy with other electrically conductive materials.

### TECHNICAL FIELD

The present disclosure generally related to crossbar array circuits with Resistive Random-Access Memory (RRAM) and more specifically to providing RRAM-based crossbar array circuit with improved Low-Resistance State (LRS) data retention and reliability.

### BACKGROUND

Traditionally, a crossbar array circuit may include horizontal metal wire rows and vertical metal wire columns (or other electrodes) intersecting with each other, with crossbar devices formed at the intersecting points. A crossbar array may be used in non-volatile solid-state memory, signal processing, control systems, high-speed image processing systems, neural network systems, and so on.

A RRAM is a two-terminal passive device capable of changing resistance responsive to sufficient electrical stimulations, which have attracted significant attention for high-performance non-volatile memory applications. The resistance of a RRAM may be electrically switched between two states: a High-Resistance State (HRS) and a Low-Resistance State (LRS). The switching event from a FIRS to a LRS is often referred to as a “Set” or “On” switch; the switching systems from a LRS to a FIRS is often referred to as a “Reset” or “Off” switching process.

### SUMMARY

Technologies relating to providing RRAM-based crossbar array circuit with improved LRS data retention and reliability are disclosed.

An apparatus, in some implementations, includes: a bottom electrode; a filament forming layer formed on the bottom electrode; and a top electrode formed on the filament forming layer. The filament forming layer is configured to form a filament within the filament forming layer responsive to a determination that a switching voltage has been applied to the filament forming layer. The filament forming layer is made of one of the following materials: HfOxSiy, HfOxNy, HfOxAly, HfOx doped with SiO2, HfOx doped with Al2O3, HfOx doped with N, HfOx doped with Si₃N₄, HfOx doped with AlN, or a combination thereof

In some implementations, the bottom electrode or the top electrode is made of one of the following materials: Pt, Ti, TiN, Pd, Ir, W, Ta, Hf, Nb, V, Ru, TaN, NbN, a combination therefore, or an alloy with other electrically conductive materials.

In some implementations, the apparatus further includes: a passivation layer isolated the filament forming layer, the bottom electrode, and the top electrode, from the bottom wire and the top wire, wherein the passivation layer is made of one of the following materials: Al₂O₃, SiO₂, Si₃N₄, AlN, MgO, SiOₓN_{y}, AlOₓN_{y}, or a combination thereof

In some implementations, a material of the bottom wire or the top wire includes Al, Au, Cu, Fe, Ni, Mo, Pt, Pd, Ti, TiN, Ru, W, TaN, or any combination or alloy of other electrically conductive materials thereof

In some implementations, the apparatus further includes: a substrate on which the bottom wire is formed, and the substrate is made of one of the following materials: Si, Si₃N₄, SiO₂, Al₂O₃, AlN, or a combination thereof.

### BRIEF DESCRIPTION OF THE DRAWINGS

FIG. 1A is a block diagram illustrating an example crossbar array circuit in accordance with some implementations of the present disclosure.

FIG. 1B is a block diagram illustrating a partially enlarged view of an example crossbar device in accordance with some implementations of the present disclosure.

FIG. 2 is a block diagram illustrating an RRAM device in accordance with some implementations of the present disclosure.

FIG. 3 is a comparison table of activation energy and oxygen diffusion rate of Ta2O5 and HfO2.

FIG. 4 is a table of calculated exchange activation barrier of interstitial oxygen in different charge states in HfO₂ with and without Al substitution.

The implementations disclosed herein are illustrated by way of example, and not by way of limitation, in the figures of the accompanying drawings. Like reference numerals refer to corresponding parts throughout the drawings.

### DETAILED DESCRIPTION

Technologies relating to providing RRAM-based crossbar array circuit with improved LRS data retention and reliability are disclosed. The technologies described in the present disclosure may provide the following technical advantages.

The disclosed technologies improve data retention reliability during LRS operations in RRAM-based crossbar array circuits. Generally, one of the RRAM retention failure modes is the increasing LRS resistance to cause bit error or memory loss. And the root cause of increasing LRS resistance is the erosion of conductive filament in the RRAM during the LRS operation. The present disclosure provides several mechanisms of the conductive filament erosion and corresponding solutions to suppress the erosion.

First, by increasing the oxygen diffusion barrier of the filament or filament forming layer, the disclosed technology may suppress oxygen diffusion during high temperature operation.

Second, by maintaining the amorphous state of the filament or filament forming layer, the disclosed technology may prevent the formation of grain boundaries which can be the fast diffusion paths for oxygen ions.

Third, by introducing the materials that have a higher chemical stability or low oxygen diffusion coefficient, the present disclosure may extend the time duration in which a filament maintains its chemical and physical states to provide reliable data memory and therefore strengthen the filament's data retention and reliability.

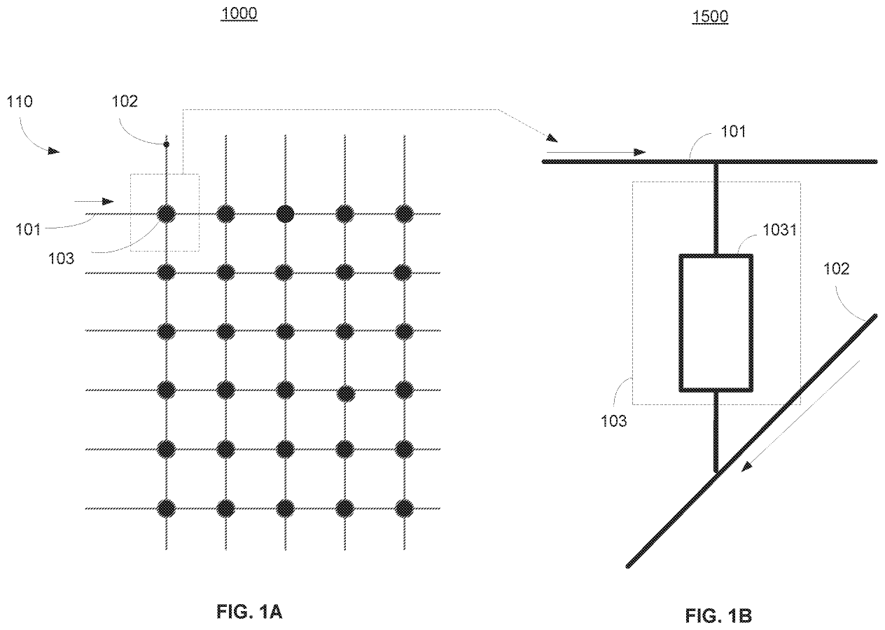

FIG. 1A is a block diagram 1000 illustrating an example crossbar array circuit 110 in accordance with some implementations of the present disclosure. As shown in FIG. 1A, the crossbar array circuit 110 includes a first row wire 101, a first column wire 102, and a crossbar device 103.

FIG. 1B shows a block diagram 1500 illustrating a partially enlarged view of example crossbar device 103 in accordance with some implementations of the present disclosure. In FIG. 1B, the crossbar device 103 connected between the first row wire 101 and the first column wire 102 of the crossbar array circuit 110 described above. In some implementations, the crossbar device 103 includes an RRAM cell 1031. In some implementations, the RRAM cell 1031 may be a one-transistor-one-memristor (1T1R) stack, one-selector-one-memristor (1S1R), or a memristor (RRAM) stack.

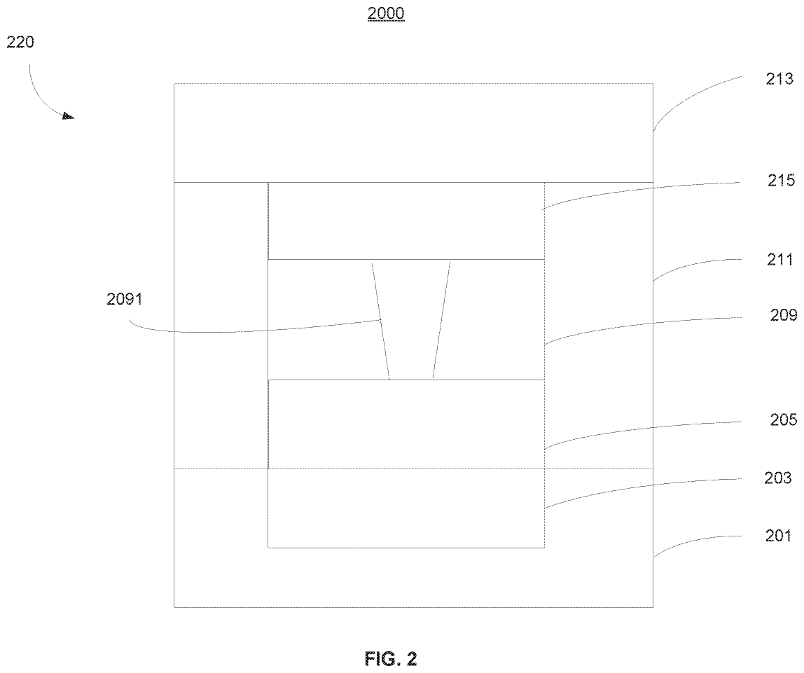

FIG. 2 shows a block diagram 2000 illustrating an RRAM cell 220 in accordance with some implementations of the present disclosure. In some implementations, the RRAM cell 220 includes a substrate 201, a column wire (bottom wire) 203 formed on the substrate 201, a bottom electrode 205 formed on column wire 203, a filament forming layer 209 formed on the bottom electrode 205, a top electrode 215 formed on the filament forming layer 209, a row wire (top wire) 213 formed on the top electrode 215, and a passivation layer 211 isolated the filament forming layer 209, the bottom electrode 205, and the top electrode 215, from the column wire 203 and the row wire 213.

The substrate 201 is, in some implementations, made of one of the following materials: Si, Si₃N₄, SᵢO₂, Al₂O₃, AlN, and a combination thereof. The passivation layer 211 is, in some implementations, made of one of the following materials: Al₂O₃, SiO₂, Si₃N₄, MgO, SiOxNy, AlOxNy, and a combination thereof

The column wire 203 is, in some implementations, made of one of the following materials: Al, Au, Cu, W, Fe, Ni, Mo, Pt, Pd, Ti, TiN, TaN, a combination thereof, and an alloy with alloy with one or more other electrically conductive materials. Similarly, the row wire 213 is, in some implementations, made of one of the following materials: Al, Au, Cu, W, Fe, Ni, Mo, Pt, Pd, Ti, TiN, TaN a combination thereof, and an alloy with alloy with one or more other electrically conductive materials.

The bottom electrode 205 is, in some implementations, made of one of the following materials: Pt, Ti, TiN, Pd, Ir, W, Ta, Hf, Nb, V, Ru, TaN, NbN, a combination thereof, and an alloy with alloy with one or more other electrically conductive materials. Similarly, the top electrode 215 is, in some implementations, made of one of the following materials: Pt, Ti, TiN, Pd, Ir, W, Ta, Hf, Nb, V, Ru TaN, NbN, a combination thereof, and an alloy with alloy with one or more other electrically conductive materials. The bottom electrode 205, the top electrode 215, or both, are used to provide better ohmic contact.

The filament forming layer 209 is, in some implementations, made of one of the following materials: TaOₓ (where x≤2.5), HfOₓ (where x≤2.0), TiOₓ (where x≤2.0), ZrOₓ (where x≤2.0), and a combination thereof. The filament forming layer 209 may be configured to form a filament 2091 within the filament forming layer 209, responsive to a set voltage/current being applied to the RRAM device 220. The filament 2091, in some implementations, includes a metal-rich or an oxygen vacancy-rich filament.

As explained above, an RRAM-based crossbar array circuit may be used in an analog memory-based accelerator with the analog resistances in LRS. While it has excellent memory characteristics and great potential in all kinds of applications, reliability and data retention become a challenge.

Reliability tests have shown that RRAM retention failures occur when LRS resistance increases, causing bit error or memory loss. The increased LRS resistance is caused by the erosion of Conductive Filament (CF), due to oxygen diffusion toward a conductive filament from the filament forming layer. The erosion causes the filament to become thinner or weaker over time and thus increases the LRS resistance over time.

The present disclosure provides several technical solutions to prevent the erosion of Conductive Filament (CF): increasing oxygen diffusion barrier, reducing oxygen diffusivity, maintaining the amorphous state of the filament or filament forming layer (e.g., increasing amorphous to crystalline transition temperature of RRAM oxide to eliminate the grain boundaries which may act as fast diffusion paths). These technical solutions reduce the likelihood that oxygen ions diffuse from the filament forming layer 209 to the filament 2091 and strengthen the filament against erosion with time and improve RRAM's data retention.

To these ends, therefore, in some implementations, the filament forming layer 209 is made of one of the following materials: HfOₓSi_{y}, HfOₓN_{y}, HfOₓAl_{y}, HfOₓ doped with SiO₂, HfOₓ doped with Al₂O₃, HfOₓ doped with N, HfOₓ doped with Si₃N₄, HfOₓ doped with AlN, or a combination thereof. The HfOₓ of the filament forming layer 209 may be substituted or combined with other RRAM oxide materials, for example, TaOₓ, TiOx, and ZrOₓ.

The advantages and mechanism of the material selection are disclosed as follows.

Generally, the LRS resistance gradually increases with time during the operation. In an analog RRAM, the LRS may store several bits of information with many resistance levels. For instance, to store 6 bits of information, the LRS needs to provide 64 levels of distinguishable resistance. However, when the stored LRS resistance increases with time (especially in high temperature operation) to reach the next level of resistance, memory error may occur. Specifically, when the stored LRS resistance increases above a threshold value, LRS data error occurs or retention failure occurs.

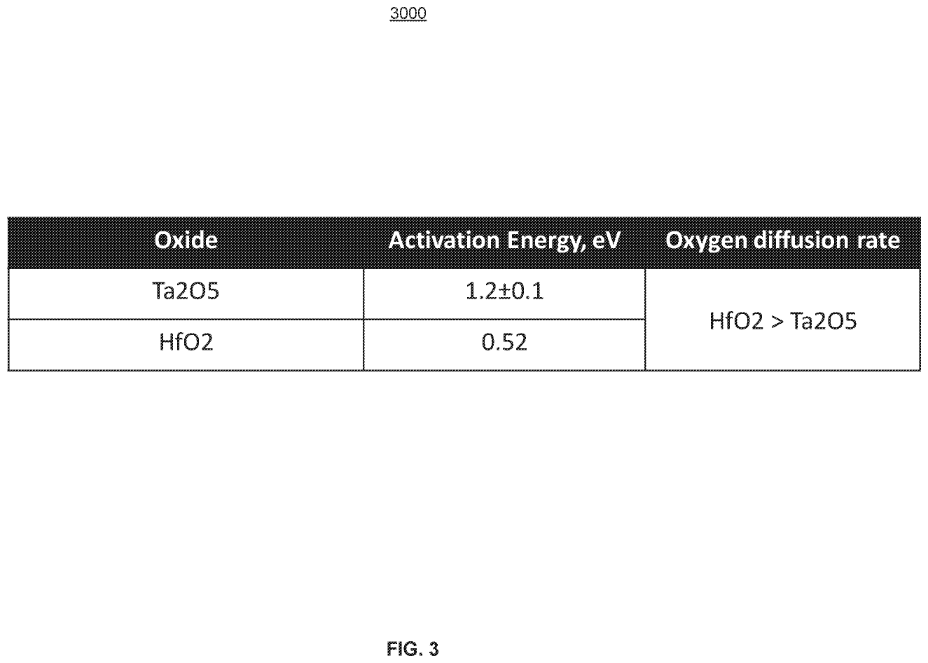

Furthermore, according to the observation that the LRS retention failure rate is faster in a HfO_{X} based RRAM than in a TaOₓ based RRAM. FIG. 3 shows the corresponding activation energy for oxygen diffusion, and oxygen diffusion rate in HfOₓ and TaOₓ. The activation energy is the energy necessary for an atom or ion to move, or the energy barrier an atom or ion to overcome for motion. The higher the activation energy, the more difficult the diffusion or the slower the diffusion rate. It is determined that activation energy for oxygen diffusion is one of the dominant factors affecting LRS data retention.

To improve LRS data retention for the HfOₓ RRAM (or other oxide RRAM), therefore, technical solutions are provided to suppress the oxygen diffusion and prevent the data loss from filament erosion.

First, technologies disclosed in the present disclosure may suppress oxygen diffusion during a high temperature operation by increasing the oxygen diffusion barrier of a filament or a filament forming layer.

Second, technologies disclosed in the present disclosure may prevent the formation of grain boundaries, which may act as a fast diffusion path for oxygen ions, by maintaining the amorphous state of a filament or a filament forming layer.

Third, technologies disclosed in the present disclosure may stabilize a filament's chemical and physical states with time and therefore strengthen the filament's ability to store data, by using materials that have a higher chemical stability or a lower oxygen diffusion coefficient.

Several example selections and their corresponding advantages are discussed below.

### HfOₓ doped with SiO₂ or HfOₓSi_{y}

As explained above, in some implementations, the HfOₓ of the filament forming layer 209 may be doped with SiO₂ or heavily doped with SiO₂ to become as a composition of HfOₓSi_{y}. Alternatively, a SiO₂ layer may be deposited into the HfOₓ of the filament forming layer 209 to form the composition of HfOₓSi_{y}.

The atomic oxygen diffusion via oxygen lattice exchange is the predominant diffusion mechanism in hafnia. The amount of exchanged oxygen increased with temperature is suppressed (or kept lower) by SiO₂. Meanwhile, the addition of SiO₂ to hafnium oxide and Hf silicate also suppresses O incorporation in the dielectric. The oxygen diffusion in the filament forming layer is therefore reduced.

Additionally, HfO₂ has a relatively low amorphous to crystalline transition temperature, for example between 300 and 500° C., depending on deposition conditions and film thickness; while SiO₂ is a stable glass former. Doping HfOx with SiO₂ may significantly increase the amorphous to crystalline transition temperature and therefore reduce the oxygen diffusion by eliminating the fast diffusion path along the grain boundaries.

### HfOₓ Doped with Al₂O₃ or HfOₓAl_{y}

In some implementations, the HfOₓ of the filament forming layer 209 may be doped with Al₂O₃, or heavily doped with Al₂O₃ to become as a composition of HfOₓAl_{y}. Alternatively, an Al₂O₃ layer is deposited into the HfOₓ of the filament forming layer 209 to form the composition of HfOₓAl_{y}.

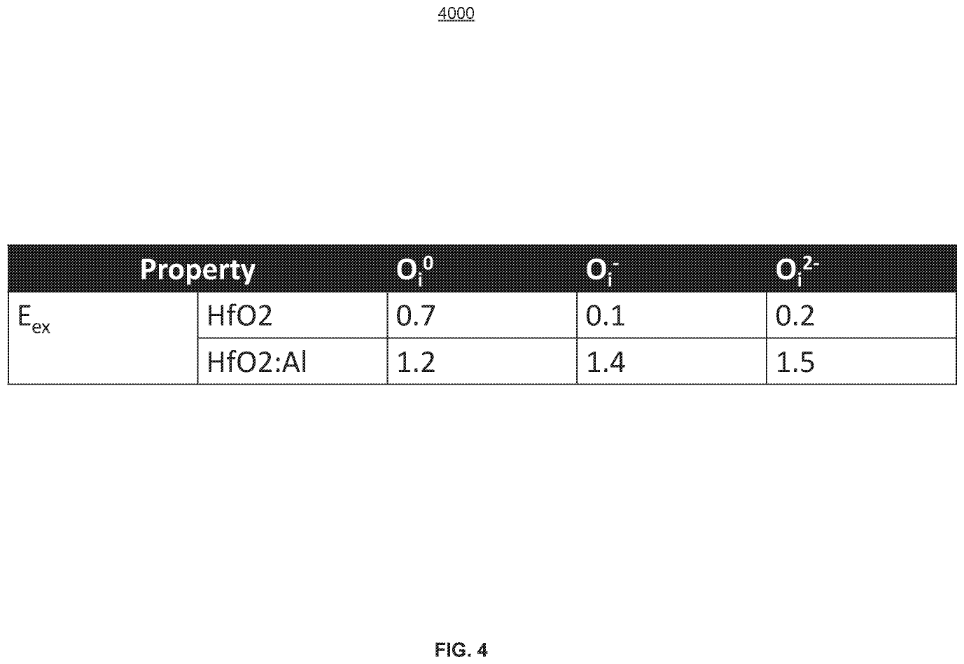

FIG. 4 shows a table on Aluminum-induced reduction of the oxygen diffusion in HfO2. Eₑₓ is the calculated exchange activation energy barriers (in eV), Oᵢ⁰, Oᵢ⁻, and Oᵢ²⁻ are oxygen atom, oxygen ion with −1 charge, and oxygen ion with −2 charge, respectively, and HfO2 and HfO2:Al are HfO2 lattice without and with Al substitutions. As shown in FIG. 4, when one of the lattice Hf atoms near the interstitial oxygen during the diffusion is substituted by an Al atom, the diffusion barrier of oxygen may increase by about 0.5 or 1.3 eV, depending on the charge state of interstitial oxygen. Meanwhile, the addition of Al also raises the diffusion barrier for interstitial oxygen, because the interstitial oxygen is strongly attracted by its neighboring Al atoms. The diffusion barrier having been increased, the overall oxygen diffusion in the filament forming layer reduces.

### HfOₓ Doped with N or HfOₓN_{y}

Further, in some implementations, the HfO_{X} of the filament forming layer 209 may be doped with N or heavily doped with N to form the composition of HfOₓN_{y}.

An HfOₓN_{y} film suppresses oxygen diffusion during high temperature annealing or operation. A phase transition of HfOₓ from an amorphous state to a crystalline or polycrystalline state is about 400° C. However, the HfOₓN_{y} film may remain amorphous after 800° C. annealing in N₂ ambient. Meanwhile, the remaining RRAM in amorphous state may prevent the formation of grain boundaries, which may provide one or more fast diffusion paths for oxygen ions. Maintaining amorphous state of the filament forming layer during a high temperature operation reduces oxygen diffusion in these situations.

### HfOₓ Doped with Si₃N₄

Still further, in some implementations, the HfOₓ of the filament forming layer 209 may be doped with Si₃N₄.

In Si technology, Si₃N₄ may be used as passivation, insulator, diffusion barrier, or an etch stop layer. Si₃N₄ may be used as masking materials in a silicon oxidation process due to its high chemical stability and low oxygen diffusion coefficient. It is therefore an excellent candidate for an oxygen diffusion barrier. Meanwhile, a phase transition of Si₃N₄ from amorphous to α-phase occurred at a temperature above 1400° C. A crystallization process is completed after receiving a heat treatment at 1500° C. for three hours or at 1550° C. for one hour. By doping Si₃N₄ into HfOₓ, the amorphous state of the filament forming layer may be maintained during a high temperature operation, reducing oxygen diffusion, reducing filament erosion, and improving RRAM data retention.

In some implementations, other RRAM oxide materials (including TaOₓ, TiOₓ, or ZrOₓ) may also be doped with any of the materials mentioned above or in any combination with any of the materials mentioned above.

Plural instances may be provided for components, operations or structures described herein as a single instance. Finally, boundaries between various components, operations, and data stores are somewhat arbitrary, and particular operations are illustrated in the context of specific illustrative configurations. Other allocations of functionality are envisioned and may fall within the scope of the implementation(s). In general, structures and functionality presented as separate components in the example configurations may be implemented as a combined structure or component. Similarly, structures and functionality presented as a single component may be implemented as separate components. These and other variations, modifications, additions, and improvements fall within the scope of the implementation(s).

It will also be understood that, although the terms “first,” “second,” etc. may be used herein to describe various elements, these elements should not be limited by these terms. These terms are only used to distinguish one element from another. For example, a first column could be termed a second column, and, similarly, a second column could be termed the first column, without changing the meaning of the description, so long as all occurrences of the “first column” are renamed consistently and all occurrences of the “second column” are renamed consistently. The first column and the second are columns both column s, but they are not the same column.

The terminology used herein is for the purpose of describing particular implementations only and is not intended to be limiting of the claims. As used in the description of the implementations and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” may be construed to mean “when” or “upon” or “in response to determining” or “in accordance with a determination” or “in response to detecting,” that a stated condition precedent is true, depending on the context. Similarly, the phrase “if it is determined (that a stated condition precedent is true)” or “if (a stated condition precedent is true)” or “when (a stated condition precedent is true)” may be construed to mean “upon determining” or “in response to determining” or “in accordance with a determination” or “upon detecting” or “in response to detecting” that the stated condition precedent is true, depending on the context.

The foregoing description included example systems, methods, techniques, instruction sequences, and computing machine program products that embody illustrative implementations. For purposes of explanation, numerous specific details were set forth in order to provide an understanding of various implementations of the inventive subject matter. It will be evident, however, to those skilled in the art that implementations of the inventive subject matter may be practiced without these specific details. In general, well-known instruction instances, protocols, structures, and techniques have not been shown in detail.

The foregoing description, for purpose of explanation, has been described with reference to specific implementations. However, the illustrative discussions above are not intended to be exhaustive or to limit the implementations to the precise forms disclosed. Many modifications and variations are possible in view of the above teachings. The implementations were chosen and described in order to best explain the principles and their practical applications, to thereby enable others skilled in the art to best utilize the implementations and various implementations with various modifications as are suited to the particular use contemplated.

What is claimed is:

1. An apparatus comprising:
a bottom electrode;
a filament forming layer formed on the bottom electrode; and
a top electrode formed on the filament forming layer, wherein
the filament forming layer is configured to form a filament within the filament forming layer responsive to a determination that a switching voltage has been applied to the filament forming layer, and wherein
the filament forming layer is made of one of the following materials: HfOₓSi_{y}, HfOₓN_{y}, HfOₓAl_{y}, HfOₓ doped with SiO₂, HfOₓ doped with Al₂O₃, HfOₓ doped with N, HfO_{X} doped with Si₃N₄, HfO_{X} doped with AlN, or a combination thereof.

2. The apparatus as claimed in claim 1, wherein the bottom electrode or the top electrode is made of one of the following materials: Pt, Ti, TiN, Pd, Ir, W, Ta, Hf, Nb, V, Ru, TaN, NbN, a combination therefore, or an alloy with other electrically conductive materials.

3. The apparatus as claimed in claim 1, further comprises:
a bottom wire; and
a top wire, wherein
the bottom electrode is formed on the bottom wire, and
the top wire is formed on the top electrode.

4. The apparatus as claimed in claim 3, wherein the bottom wire or the top wire is made of one of the following materials: Al, Au, Cu, Fe, Ni, Mo, Pt, Pd, Ti, TiN, Ru, W, TaN, a combination therefore, or an alloy with other electrically conductive materials.

5. The apparatus as claimed in claim 3, further comprises a passivation layer isolated the filament forming layer, the bottom electrode, and the top electrode, from the bottom wire and the top wire, wherein the passivation layer is made of one of the following materials: Al₂O₃, SiO₂, Si₃N₄, AlN, MgO, SiOₓN_{y}, AlOₓN_{y}, or a combination thereof

6. The apparatus as claimed in claim 3, further comprises:
a substrate, wherein the bottom wire formed on the substrate, and
the substrate is made of one of the following materials: Si, Si₃N₄, SiO₂, Al₂O₃, AlN, or a combination thereof.
